(19) United States
(12) Patent Application Publication
(10) Pub. No.: US 2026/0124828 A1
(43) Pub. Date: May 7, 2026

(54) PACKAGING SOLUTION

(71) Applicant: METAPAC INC., Vaughan (CA)

(72) Inventors: Pranav Sultania, Pickering (CA); Divya Lal, Vaughan (CA); Tanya Khanna, Brampton (CA)

(21) Appl. No.: 19/375,107

(22) Filed: Oct. 30, 2025

Related U.S. Application Data
(60) Provisional application No. 63/715,461, filed on Nov. 1, 2024.
(60) Provisional application No. 63/735,173, filed on Dec. 17, 2024.

(51) Int. Cl. B32B 27/32; B32B 7/14; C23C 16/06

(52) U.S. Cl. CPC B32B 27/32; B32B 7/14; C23C 16/06; B32B 2250/24; B32B 2307/304; B32B 2307/31; B32B 2439/70

(57) ABSTRACT

A packaging assembly for perishable items including food, beverages, pharmaceuticals, and/or biological materials. The packaging includes one or more components configured to maintain and/or control the temperature of the package. The packaging assembly includes a first box at least partially laminated with a metallized film, a liner positionable inside the first box, a second box positionable inside the liner, a cooling agent positionable inside the liner, and an air cushion panel positionable inside the liner.

### INCORPORATION BY REFERENCE TO ANY PRIORITY APPLICATIONS

Any and all applications for which a foreign or domestic priority claim is identified in the application data sheet as filed with the present application are hereby incorporated by reference under 37 C.F.R. § 1.57. The present application claims priority to U.S. Provisional Patent Application No. 63/715,461, filed Nov. 1, 2024, titled PACKAGING SOLUTION, and U.S. Provisional Patent Application No. 63/735,173, filed Dec. 17, 2024, titled PACKAGING SOLUTION the entire content of each of which is incorporated by reference herein for all purposes and forms as part of this specification.

### BACKGROUND

The application is generally directed to packaging assemblies for items requiring temperature controlled conditions such as food, beverages, pharmaceuticals, and/or biological materials. Existing thermal packaging solutions often employ bulky foam inserts, single-use gel packs, and/or rigid metalized shells to insulate contents.

### SUMMARY

While certain thermal packaging may slow heat transfer, they frequently suffer from high material costs, significant storage volume when not in use, and limited customization for multi-zone temperature control. In many cases, once assembled, the packaging cannot be easily adjusted or reconfigured to suit variable load sizes and/or mixed-temperature shipments. Moreover, the reliance on non-recyclable or hard-to-separate materials can contribute to environmental waste following delivery. Thus, there is a need for better packaging solution for the transportation of items requiring temperature-controlled conditions such as food, beverages, pharmaceuticals, and/or biological materials.

More specifically, the present disclosure is generally directed to containers, liners, and/or auxiliary panels used to insulate and protect items such as food, beverages, pharmaceuticals, and/or biological materials from unwanted temperature fluctuations. Ensuring the safe and reliable shipment of temperature-sensitive products is necessary to preserve quality, shelf life, and/or product efficacy.

There remains an ongoing demand for packaging systems that can reliably achieve target temperature ranges over extended periods. Ideal solutions are expected to not only insulate effectively against heat gain or loss but also offer modular adaptability to accommodate different shipment sizes and thermal requirements. Furthermore, as sustainability gains prominence, there is a growing expectation that packaging components be lightweight, reusable or recyclable, and capable of nesting or flattening to minimize warehouse footprint and/or reduce carbon emissions associated with storage and transport.

There is provided in accordance with one aspect of the present disclosure, a packaging assembly for perishable items. The packaging solution can include a first box at least partially laminated with a metallized film, a liner positioned inside the first box, a second box positioned inside the liner, a cooling agent positioned inside the liner, and/or an air cushion panel positioned inside the liner.

The metallized film can include a metallized polyethylene terephthalate (PET) film.

In some aspects, the interior surface of the first box may be laminated with the metallized film.

The liner may include a first layer of metallized low-density polyethylene film and/or a second layer of polyethylene-based bubble film.

In some cases, the liner can include an adhesive strip configured to secure the liner to an interior surface of the first box.

The second layer can include one or more layers.

In some aspects, the one or more layers of the second layer can be positioned adjacent to the first layer.

In some cases, the second box can include an open top.

In some aspects, the cooling agent may be a gel pack, ice pack, or dry ice.

The air cushion panel can include a plurality of bubbles.

In some aspects, the plurality of bubbles include nitrogen.

When the second box and cooling agent are arranged inside the liner with the cooling agent atop the packaged item, the interior temperature of the second box remains lower than the ambient temperature.

In some cases, each liner of the one or more liners can be configured to be nested within another liner of the one or more liners.

In some cases, the liner can be configured to be removed from the first box for recycling.

The second box can include an open top and/or one or more vents along its bottom.

There is also provided in accordance with one aspect of the present disclosure, a liner for a packaging assembly. The liner can include a metallized low-density polyethylene film outer layer, a polyethylene-based bubble film inner layer, and an adhesive strip on the outer layer configured to secure the liner to a box interior.

In some aspects, the metallized film layer serves as the outermost layer and the bubble film layer serves as the innermost layer.

In some cases, the second layer can include two layers of polyethylene based bubble film.

There is also provided in accordance with one aspect of the present disclosure, a packaging assembly for perishable items. The packaging assembly can include a first box; and a liner positionable inside the first box, the liner comprising, a first layer comprising a metallized low-density polyethylene (LDPE) film; a second layer comprising at least one polyethylene based bubble film; and/or an adhesive strip positioned on the first layer, the adhesive strip configured to secure the liner to an interior surface of the first box.

In some aspects, the first layer is an outermost layer of the liner, and the second layer is an innermost layer of the liner.

The second layer comprises two layers of polyethylene based bubble film.

In some cases, the first box can be at least partially laminated with a metallized film.

In some aspects, the packaging assembly can include a second box positionable inside the liner.

The packaging assembly can include a cooling agent positionable inside the liner.

In some cases, the packaging assembly can include an air cushion positionable inside the liner.

In some aspects, the first layer is configured to nest against an inner surface of the first box.

These and other features will be more clearly understood from the following detailed description taken in conjunction with the accompanying drawings and claims.

### BRIEF DESCRIPTION OF THE DRAWINGS

FIG. 1 illustrates an example of a package for transporting perishable items.

FIGS. 2A-2B show examples of a first box for transporting perishable items.

FIGS. 3A-3E show examples of a liner.

FIGS. 4A-4B show examples of a second box.

FIGS. 5A-5C show examples of an air cushion panel.

FIGS. 6A-6B show examples of a box cover.

### DETAILED DESCRIPTION

Described herein is a packaging solution for perishable items including food, beverages, pharmaceuticals, and/or biological materials. The packaging solution can include one or more components configured to maintain and/or control the temperature of the package to better preserve perishable items during transportation. The packaging solution can negate inconsistent temperature control within the package or predetermined areas or portions of the package, leading to spoilage or degradation of perishable goods. This can beneficially prevent perishable items from spoiling or degrading during transportation from or to, for example, a food processing facility, a distribution center, a consumer's residence, a retail store, etc.

The packaging solution can be used across various industries. Unlike traditional packaging solutions, which tend to have a negative environmental impact and are less sustainable, the packaging solutions described herein are designed to be highly sustainable and require minimal storage space. For instance, flattened boxes of packaging assembly and its components require less storage space than existing packaging solutions. Further, material used in the packaging solutions described herein are environmentally friendly. The packaging solutions described herein can be crafted from various materials to enhance sustainability.

The packaging solutions described herein can be scaled to meet the needs of different supply chain sizes, and/or temperature range requirements for small local networks to large international logistics operations. This can beneficially ensure optimal preservation of products, reduce energy consumption, reduce waste, and/or ensure quality. By reducing energy consumption and/or minimizing waste, the packaging solutions described herein can lower operating costs over time.

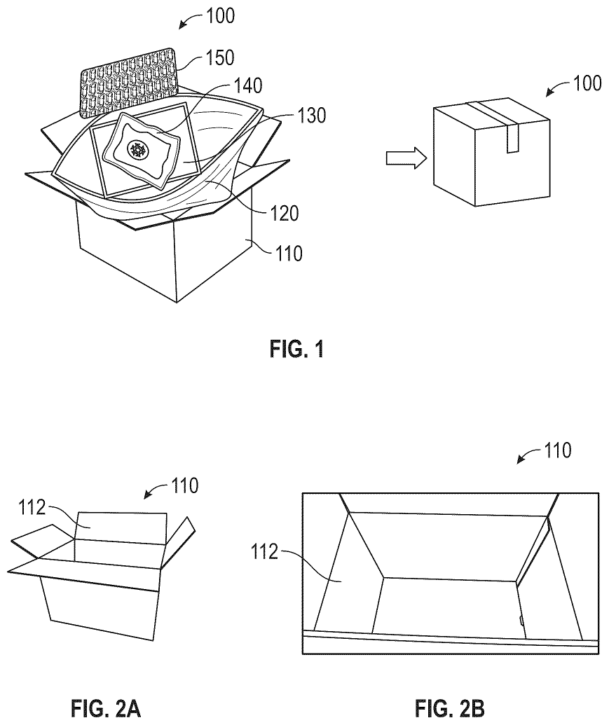

The packaging solution, also referred to as MetaFlexShield or MFS herein, can include a package 100 including one or more layers and/or components. In some cases, as shown in FIG. 1, the package 100 can include a first box 110, a liner 120, a second box 130, a cooling agent 140, an air cushion panel 150, and/or a box cover 160. As further described below, the liner 120, the second box 130, the cooling agent 140, and/or the air cushion panel 150, are positionable within each other and/or within the first box 110. Any of the components of the package 100 can be fully or partially recyclable. Although reference is made to the package 100 including multiple layers and/or components, the package can include more than or less layers and/or components recited herein. For example, not all packages 100 include a second box. As another example, multiple liners 120 can be included. Thus, the packaging solution offers a modular solution in which the components of the packaging solution can be easily added or removed to provide custom packaging for different applications or scales.

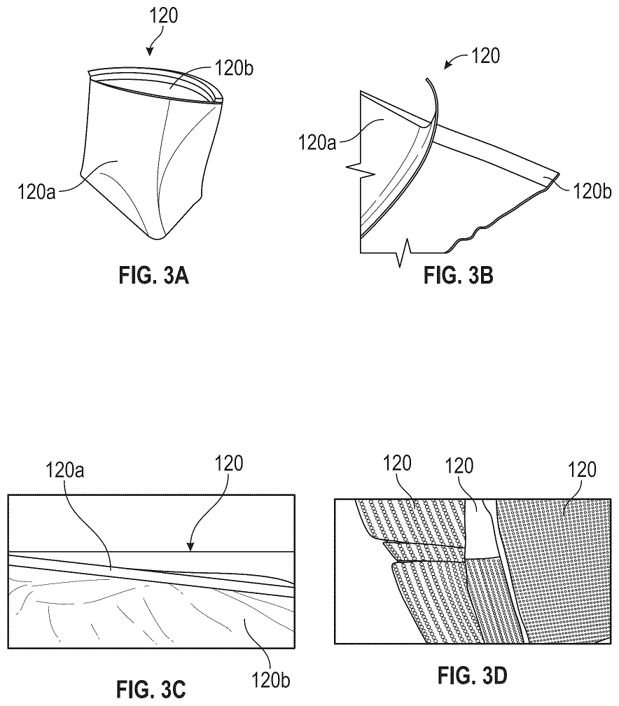

The first box 110 can include a regular slotted container (also referred herein to as “RSC”) box. The first box 110 can be made from a kraft board material. In some cases, the first box 110 can be at least partially laminated. For example, the exterior surface and/or the interior surface of the first box 110 can be laminated with a metallized polyethylene terephthalate (PET) film 112, as shown in FIGS. 2A and 2B. Laminated boxes can beneficially offer additional thermal insulation. The first box 110 can serve as a primary protective barrier during transit. The first box 110 can beneficially protect the contents from external physical damage, environmental factors, and/or contaminants.

As shown in TABLE I, the first box 110, which is identified as MFS Box in TABLE I, can have different dimensions. This can beneficially allow the first box 110 to accommodate shipments of various dimensions. The first box 110 can include at least four different sizes. The first box 110 can have a usable volume from about 2000 in³ to about 8500 in³. For example, the first box 110 can have a usable volume from about 2500 in³ to about 7500 in³, from about 3000 in³ to about 7000 in³, from about 3500 in³ to about 6500 in³, from about 4000 in³ to about 6000 in³, and/or from about 4500 in³ to about 5500 in³.

TABLE I
Package (Kit) Size and First Box Dimensions

| | MFS Box | MFS Box | MFS Box | MFS Box |
|---|---|---|---|---|
| MFS Size | Length | Width | Height | Volume |
| Medium | 18 | 12 | 12 | 2592 |
| Regular | 20 | 14 | 14 | 3920 |
| Current | 23.25 | 15 | 15.5 | 5405.625 |
| XL | 26 | 16 | 19 | 7904 |

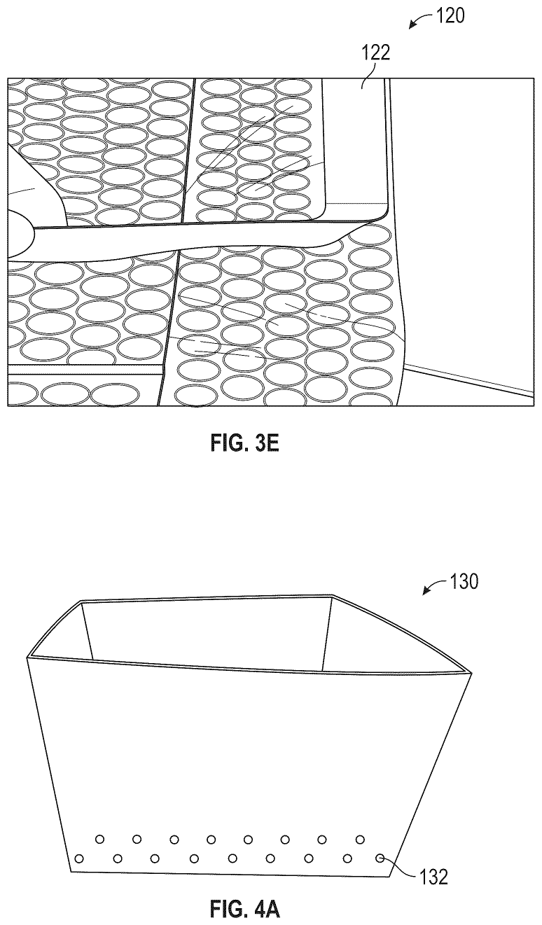

FIGS. 3A-3E show examples of liners 120. The liner 120 can provide insulation, which can beneficially maintain and/or regulate the temperature of the package 100. The liner 120 can regulate the temperature by, for example, reducing heat transfer between the contents of the package 100 and the external environment, which can ensure that the contents of the package 100 stay at the desired temperature for a longer duration. The liner 120 can include a bag. In some cases, the liner 120 can be positioned inside the first box 110. Each liner 120 can be made from first layer 120a and a second layer 120b, as shown in FIG. 3B. The first layer 120a can include at least one layer of metallized low-density polyethylene (LDPE) film and the second layer 120b can include at least one layer of polyethylene based bubble film. In some cases, the second layer 120b can be positioned adjacent to the first layer 120a. The second layer 120b can be laminated to the first layer 120a. In some cases, each liner 120 can include one, two, three, etc., layers of polyethylene based bubble film for each layer of metallized LDPE that are laminated or otherwise attached to corresponding adjacent one or more layers. For example, each liner 120 can include one layer of polyethylene based bubble film for each layer of metallized LDPE (e.g., a 1:1 ratio), and/or two layers of polyethylene based bubble film for each layer of metallized LDPE (e.g., a 1:2 ratio). Providing more second layers 120b can increase the number and total volume of air cells to provide better temperature control and product protection during transit. In some cases, each liner 120 can include one, two, three, etc., layers of metallized LDPE for each layer of polyethylene based bubble film.

Since metalized LDPE film layers are more rigid and/or uniform than polyethylene based bubble film layers, the use of one or more metalized LDPE film layers can provide structure and further support to the liner 120. In some cases, the metalized LDPE film layer can include one or more relatively planar surfaces. The one or more relatively planar surfaces can allow the liner 120 to extend along and/or cover an inner surface of the first box 110. The metalized LDPE film layers of the liner 120 can define one or more corners forming edges that are relatively more defined than edges that would be formed by a layer of bubble film. The corners and more defined edges of the liner 120 can allow the liner 120 to nest with the corners inside the first box 110 defined by inner surfaces of the first box 110 and/or PET film 112 to form a tight fit or snug fit between the first box 110 and the liner 120, minimizing space or voids between the between the first box 110 and the liner 120 for increased insulation and structural integrity of the system.

The use of a metalized LDPE film layer with a polyethylene based bubble film layer can make the liner highly sustainable as each individual layer can be reused and easily recycled, which may reduce overall plastic use. For example, each layer of metalized LDPE film and/or polyethylene based bubble film can be separated from each other. This can beneficially allow each layer to be reused in another shipment and/or for other applications after shipping is complete. In some cases, the one or more metalized LDPE film layers and/or polyethylene based bubble film layers can be adhered to each other using glue. The glue can allow the one or more layers to stay adhered to each other during shipping, but allow the one or more layers to be separated from each other as needed. The one or more layers can be re-adhered to each other and/or to other layers by, for example, reapplying glue and/or applying heat to the existing glue. The metallized LDPE layer can also act as an insulator by preventing heat transmission from radiation. Metallized LDPE is also lighter than polymers used in packaging, which may result in lighter packaging assemblies.

As shown in FIG. 3C, the first layer 120a and the second layer 120b of the liner 120 can be opposite or face each other. For example, the first layer 120a can be positioned on one side of the second layer 120b. In some cases, the first layer 120a can be the outermost layer and the second layer 120b can be the innermost layer of the liner 120, as shown in FIG. 3A. The first layer 120a can be the innermost layer and the second layer 120b can be the outermost layer of the liner 120. In some cases, the first layer 120a can be positioned between at least two second layers 120b, or the second layer 120b can be positioned between at least two first layers 120a.

Although reference is made to the package 100 including a liner 120, the package 100 can include more than one liner 120, as shown in FIG. 3D. For example, the package 100 can include 2, 3, 4, etc. liners 120. More or less liners 120 can be used depending on transit time and/or environmental conditions. The use of additional liners 120 can maintain the temperature inside the liners 120 and/or the package 100 for a longer duration of time. Packages 100 including more than one liner 120 can include a first liner of a first size and a second liner of a second size. In some cases, the first size can be larger than the second size. The first liner can receive the second liner. The first and second liners can include different materials. For example, the first liner, which can serve as an outer layer, can include a more rigid material that can provide structural integrity and/or basic insulation. The second liner, which can serve as an inner layer, can include a more flexible liner that can be arranged to offer additional insulation and/or cushioning tailored to the specific products being shipped. In some cases, the one or more liners 120 can be removably attached to each other. The one or more liners 120 can interconnect and/or nest within each other, to provide a cohesive or integrated unit that can be easily assembled and disassembled. Depending on the shipment requirements as discussed herein, the liner configuration can be adjusted. For example, one or more layers can be added or removed depending on transit times (e.g., more layers for longer transit times) or harsher environmental conditions (e.g., more layers for hotter environments).

As shown in TABLE II, the liner 120 can have different dimensions. This can beneficially allow the package 100 to accommodate shipments of various dimensions. The size of the liner 120 may depend on the size of the package (or kit) 100 to be used. The liner 120 can include at least four different sizes. Each liner 120 can have a usable volume from about 1500 in³ to about 7000 in³. For example, each liner 120 can have a usable volume from about 2000 in³ to about 6000 in³, from about 2500 in³ to about 5500 in³, from about 3000 in³ to about 5000 in³, from about 3500 in³ to about 4500 in³, and/or from about 4000 in³ to about 4250 in³.

TABLE II
Package (Kit) Size and Liner Dimensions

| | MFS Box Liner's Dims | | | | | | |
|---|---|---|---|---|---|---|---|
| | | | | | | | Approx. |
| | | | | | | | Usable |
| | | | | | | | Volume |
| | | | | | | | inclusive of |
| | | | | | Usable | | Space for Air |
| | | Bottom | | Usable | Bottom | Usable | cushion panel |
| Kit Size | Length | Gusset | Height | Length | Gusset | Height | and Dry ice |
| Medium | 29.53 | 11.81 | 19.29 | 15.00 | 11.00 | 11.00 | 1815.00 |
| Regular | 33.46 | 13.78 | 22.05 | 17.00 | 13.00 | 13.00 | 2873.00 |
| Current | 35.04 | 12.99 | 20.87 | 20.5 | 14.5 | 14 | 4161.50 |
| XL | 41.34 | 15.75 | 27.95 | 23.00 | 15.00 | 18.00 | 6210.00 |

The liner 120 can be removably secured inside the first box 110. This can beneficially allow a liner 120 to be used more than once, used in different packages 100, and/or recycled. In some cases, the liner 120 can include adhesive to secure the liner 120 inside the first box 110. For example, the liner 120 can include an adhesive strip 122, as shown in FIG. 3E. The adhesive strip 122 can be positioned along an edge of the liner 120. To secure the liner 120 to the first box 110, the adhesive strip can be fixed to an interior surface of the first box 110. Fixing the liner 120 to the first box 110 can beneficially seal the liner 120 to the first box 110 thus maintaining structural integrity and preventing leaks. In some cases, the liner 120 can be secured to the first box 110 by heat sealing the liner 120 to the first box 110. The adhesive strip 122 can also be used to secure one liner 120 to another liner 120. For example, to secure one liner 120 to another liner 120, the adhesive strip 122 of one liner 120 can be fixed to an interior surface of the other liner 120. Each liner 120 can include an adhesive strip 122 to secure as many liners to each other as needed.

In some cases, the first layer 120a and the second layer 120b of the liner 120 can be separated from each other. This can allow the first layer 120a and the second layer 120b to be disposed of and/or recycled separately. FIG. 3B shows an example a first layer 120a partially separated from the second layer 120b.

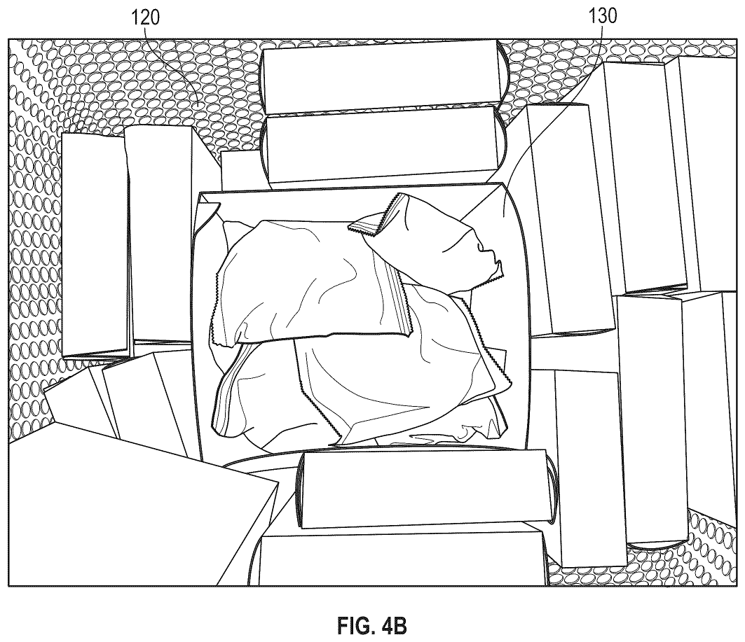

The second box 130 can be positioned inside the first box 110 and/or the liner 120. In some cases, the second box 130 can be smaller than the first box 110 and/or the liner 120. The second box 130 can include one or more vents 132, as shown in FIG. 4A. The one or more vents can include slots (e.g., holes along the second box 130). In some cases, the one or more vents 132 can be positioned along a bottom portion of the second box 130. At least some of the contents of the packaging 100 (e.g., the goods to be shipped, transported), can be positioned inside the second box 130. Like the first box 110, the second box 130 can include an RSC box and/or be made from a kraft board material.

In some cases, the second box 130 does not include a lid (e.g., inner and/or outer flaps; has an open top), as shown in FIG. 4A. Since colder air tends to move or sink because relatively colder air is heavier and denser than warmer air, positing the second box having an open top on a bottom portion of the first box 110 and/or the liner 120 can help the second box 130 maintain a temperature lower than the overall temperature inside the package 100. In some cases, the second box 130 is positioned below the cooling agent 140 for the relatively colder air from the cooling agent 140 to move downward into the second box 130. The second box 130 can be without a lid to allow and facilitate movement of air downward into the second box 130. Thus, items requiring a lower storage temperature can be positioned in the second box 130. For instance, the second box 130 can be used for holding items that are more sensitive to temperature changes and thaw faster. Other, less temperature-sensitive, items can be positioned inside the liner 120 but outside the second box 130, as shown in FIG. 4B. For example, one or more items can be positioned around and/or beneath the second box 130. The one or more vents 132 can beneficially allow for continuous flow of cold air to the second box 130 and/or bottom portions thereof.

The cooling agent 140 can include gel packs, ice packs, dry ice, etc., or a combination thereof. The cooling agent 140 can be positioned anywhere inside the package 100. For example, the cooling agent 140 can be positioned inside the liner 120 and/or the second box 130. In some cases, the cooling agent 140 can be positioned on top of, beneath, and/or around the items being shipped. The use of a cooling agent 140 can beneficially help maintain the temperature inside the package 100. The amount/quantity of cooling agent 140 in a package 100 can vary. For example, the amount/quantity of cooling agent 140 may vary depending on geographical locations, temperature requirements, weather conditions, travel distance, size of the package 100, and/or the items being shipped. In some cases, the package 100 can include from about 1 lb. to about 25 lb. of dry ice blocks.

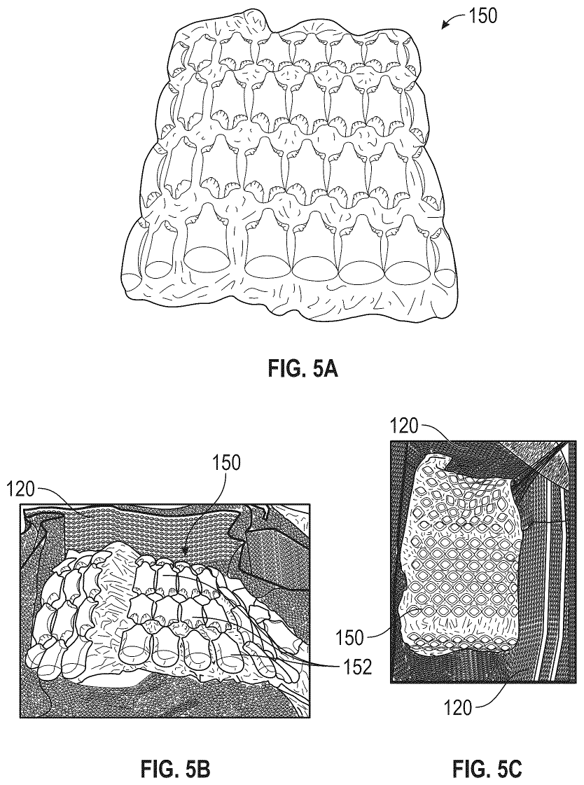

FIGS. 5A-5C shows examples of air cushion panels. The package 100 can include one or more air cushion panels 150. In some cases, the air cushion panels 150 can be made of a metallized polyethylene (PE) heat sealable film. The air cushion panels 150 can include a plurality of bubbles 152 (e.g., pockets), as shown in FIG. 5B. The plurality of bubbles 152 can be formed within one or more internal layers of the air cushion panels 150. In some cases, the plurality of bubbles 152 can include nitrogen. The plurality of bubbles 152 can provide additional padding, improved insulation, and increased air volume. This can beneficially provide better temperature control and product protection during transit. The air cushion panels 150 can be inflated or deflated. This can allow the air cushion panels 150 to be stored when not in use.

The air cushion panels 150 can provide thermal insulation and cushioning. The cushioning can protect the items being shipped from damage by preventing and/or minimizing movement during transportation. The air cushion panels 150 can also help organize the items being shipped by providing a barrier between each item and/or set of items being shipped.

The air cushion panels can be positioned inside the first box 110, the liner 120 (as shown in FIGS. 5B-5C), and/or the second box 130. For example, the air cushion panels 150 can be positioned on top of, around, and/or beneath the items being shipped. In some cases, the air cushion panels 150 can be positioned between two or more items inside the second box 130. The cooling agent 140 can be positioned between the items being shipped and the air cushion panels 150, on top of the air cushion panels 150, and/or beneath the air cushion panels 150.

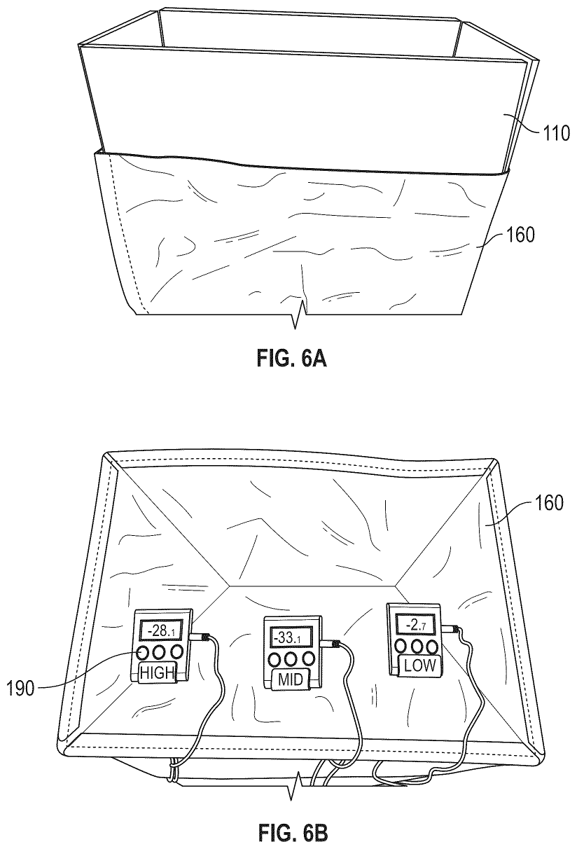

In some cases, the first box 110 (and all items inside the first box 110) can be positioned inside a box cover 160, as shown in FIGS. 6A-6B. The box cover 160 can be made of aluminum and/or polyethylene. The box cover 160 can include provide additional thermal insulation and/or protection.

Any of the packaging assemblies described herein can include one or more devices for measuring temperature. For example, the packing assemblies can include a thermocouple and/or a temperature logger. The temperature measuring devices can be positioned inside a packaging assembly to monitor the temperature inside the packaging assembly. For example, the temperature measuring devices can be positioned on or inside the first box 110, the liner 120, the second box 130, the air cushion panels 150, and/or the box cover 160. FIG. 6B shows a plurality of temperature measuring devices 190 positioned on a box cover 160.

The temperature measuring devices can include a transceiver. The transceiver can allow wireless communication between the temperature measuring devices and remote devices such as a cellphone, a computer, a central server, etc. The wireless communication can occur over a Wi-Fi, cellular, and/or Bluetooth, network. Real-time temperature tracking can be used to predict and prevent temperature excursions.

As shown in Table III, the package 100 and/some of its components can have different weights. For example, the weight of the second box 130 can range from about 100 grams to about 200 grams, and in some cases be about 150 grams. For example, the weight of the second box 130 can range from about 120 grams to about 180 grams, from about 140 grams to about 160 grams, and/or from about 145 grams to about 155 grams. The weight of each air cushion panel 150 can range from about 5 grams to about 15 grams, and in some cases be about 10 grams. For example, the weight of each air cushion panel 150 can range from about 6 grams to about 14 grams, from about 7 grams to about 13 grams, and/or from about 8 grams to about 12 grams. The weight of the first box 110 can range from about 400 grams to about 1500 grams. For example, the weight of the first box 110 can range from about 500 grams to about 1400 grams, from about 700 grams to about 1200 grams, and/or from about 900 grams to about 1000 grams. The weight of each liner 120 can range from about 200 grams to about 1000 grams. For example, the weight of each liner 120 can range from about 300 grams to about 900 grams, from about 500 grams to about 700 grams, and/or from about 550 grams to about 650 grams. The total weight of the package 100 can range from about 700 grams to about 2750 grams. For example, the total weight of the package 100 can range from about 1000 grams to about 2500 grams, from about 1500 grams to about 2000 grams, and/or from about 1700 grams to about 1800 grams. The total weight of the package 100 without a second box 130 can range from about 600 grams to about 2550 grams. For example, the total weight of the package 100 without a second box 130 can range from about 1000 grams to about 2000 grams, from about 1200 grams to about 1800 grams, and/or from about 1400 grams to about 1600 grams.

TABLE III
Package (Kit) Size and First Box Dimensions

| | Inner Box | Air Cushion | Box's | Box Liner's | Total MFS | Total MFS Kit's Weight |
|---|---|---|---|---|---|---|
| Kit Size | Weight | Panel's Weight | Weight | Weight | Kit's Weight | (no inner box) |
| Medium 10315 | N/A | 10 | 580 | 360 | 950 | 950 |
| Regular 10300 | 150 | 10 | 780 | 510 | 1450 | 1300 |
| Current 10400 + 1 | 150 | 10 | 1010 | 610 | 1780 | 1630 |
| XL 10400 + 5 | 150 | 10 | 1160 | 720 | 2040 | 1890 |

### DISCLAIMER

Although the present invention has been described in terms of certain preferred embodiments, it may be incorporated into other embodiments by persons of skill in the art in view of the disclosure herein. The scope of the invention is therefore not intended to be limited by the specific embodiments disclosed herein, but is intended to be defined by the full scope of the following claims.

Accordingly, it is to be understood that the embodiments of the invention herein described are merely illustrative of the application of the principles of the invention. Reference herein to details of the illustrated embodiments is not intended to limit the scope of the claims, which themselves recite those features regarded as essential to the invention. The drawings are for the purpose of illustrating embodiments of the invention only, and not for the purpose of limiting it.

It is contemplated that various combinations or subcombinations of the specific features and aspects of the embodiments disclosed above may be made and still fall within one or more of the inventions. Further, the disclosure herein of any particular feature, aspect, method, property, characteristic, quality, attribute, element, or the like in connection with an embodiment can be used in all other embodiments set forth herein. Accordingly, it should be understood that various features and aspects of the disclosed embodiments can be combined with or substituted for one another in order to form varying modes of the disclosed inventions. Thus, it is intended that the scope of the present inventions herein disclosed should not be limited by the particular disclosed embodiments described above. Moreover, while the invention is susceptible to various modifications, and alternative forms, specific examples thereof have been shown in the drawings and are herein described in detail. It should be understood, however, that the invention is not to be limited to the particular forms or methods disclosed, but to the contrary, the invention is to cover all modifications, equivalents, and alternatives falling within the spirit and scope of the various embodiments described and the appended claims. Any methods disclosed herein need not be performed in the order recited. The methods disclosed herein include certain actions taken by a practitioner; however, they Can also include any third-party instruction of those actions, either expressly or by implication. For example, actions such as “deploying an instrument sterilized using the systems herein” include “instructing the deployment of an instrument sterilized using the systems herein.” In addition, where features or aspects of the disclosure are described in terms of Markush groups, those skilled in the art will recognize that the disclosure is also thereby described in terms of any individual member or subgroup of members of the Markush group.

The ranges disclosed herein also encompass any and all overlap, sub-ranges, and combinations thereof. Language such as “up to,” “at least,” “greater than,” “less than,” “between,” and the like includes the number recited. Numbers preceded by a term such as “about” or “approximately” include the recited numbers. For example, “about 10 nanometers” includes “10 nanometers.”

Any titles or subheadings used herein are for organization purposes and should not be used to limit the scope of embodiments disclosed herein.

The terms “approximately”, “about”, and “substantially” as used herein represent an amount or characteristic close to the stated amount or characteristic that still performs a desired function or achieves a desired result. For example, the terms “approximately”, “about”, and “substantially” may refer to an amount in certain embodiments that is within less than plus or minus 10% of, within less than plus or minus 5% of, within less than plus or minus 1% of, within less than plus or minus 0.1% of, and within less than plus or minus 0.01% of the stated amount or characteristic.

What is claimed is:

1. A packaging assembly for perishable items, the packaging assembly comprising:
a first box at least partially laminated with a metallized film;
a liner positionable inside the first box;
a second box positionable inside the liner;
a cooling agent positionable inside the liner; and
an air cushion panel positionable inside the liner.

2. The packaging assembly of claim 1, wherein an interior surface of the first box is laminated with the metallized film.

3. The packaging assembly of claim 1, wherein the liner comprises a first layer comprising a metallized low-density polyethylene (LDPE) film, and a second layer comprising at least one layer of polyethylene based bubble film.

4. The packaging assembly of claim 1, wherein the liner comprises an adhesive strip configured to secure the liner to an interior surface of the first box.

5. The packaging assembly of claim 1, wherein the second box comprises an open top.

6. The packaging assembly of claim 1, wherein the cooling agent comprises at least one of a gel pack, an ice pack, or dry ice.

7. The packaging assembly of claim 1, wherein the air cushion panel comprises a metallized polyethylene (PE) heat sealable film.

8. The packaging assembly of claim 1, wherein the air cushion panel comprises a plurality of bubbles comprising nitrogen.

9. The packaging assembly of claim 1, wherein when the cooling agent and the second box are positioned inside the liner, and the cooling agent is positioned on top of an item inside the second box, a temperature inside the second box is lower than a temperature outside the second box.

10. The packaging assembly of claim 1, wherein the liner comprises one or more liners, and wherein each liner of the one or more liners is configured to be nested within another liner of the one or more liners.

11. The packaging assembly of claim 1, wherein the liner is secured to an interior surface of the first box.

12. The packaging assembly of claim 11, wherein the liner is secured to the interior surface of the first box via an adhesive strip positioned on the liner.

13. The packaging assembly of claim 1, wherein the second box comprises one or more vents along a bottom portion of the second box.

14. A liner for a packaging assembly, the liner comprising:
a first layer comprising a metallized low-density polyethylene (LDPE) film;
a second layer comprising at least one polyethylene based bubble film; and
an adhesive strip positioned on the first layer, the adhesive strip configured to secure the liner to an interior surface of a box.

15. The packaging assembly of claim 14, wherein the first layer is an outermost layer of the liner, and the second layer is an innermost layer of the liner.

16. A packaging assembly for perishable items, the packaging assembly comprising:
a first box; and
a liner positionable inside the first box, the liner comprising,
a first layer comprising a metallized low-density polyethylene (LDPE) film;
a second layer comprising at least one polyethylene based bubble film; and
an adhesive strip positioned on the first layer, the adhesive strip configured to secure the liner to an interior surface of the first box.

17. The packaging assembly of claim 16, wherein the first layer is an outermost layer of the liner, and the second layer is an innermost layer of the liner.

18. The packaging assembly of claim 16, wherein the first box is at least partially laminated with a metallized film.

19. The packaging assembly of claim 16, further comprising a second box positionable inside the liner.

20. The packaging assembly of claim 16, further comprising a cooling agent positionable inside the liner.

21. The packaging assembly of claim 16, further comprising an air cushion positionable inside the liner.

22. The packaging assembly of claim 16, wherein the first layer is configured to nest against an inner surface of the first box.
